(19) United States
(12) Patent Application Publication
(10) Pub. No.: US 2003/0007585 A1
(43) Pub. Date: Jan. 9, 2003

(54) Fractional-n frequency synthesizer

(76) Inventors: Declan M. Dalton, Limerick (IE); Lawrence M. DeVito, Tewksbury, MA (US); David John Hitchcox, Newbury (GB); Paul Murray, Limerick (IE)

Correspondence Address: John J. Stickevers, Bromberg & Sunstein LLP, 125 Summer Street, Boston, MA, 02110-1618, US

(21) Appl. No.: 10/094,695

(22) Filed: Mar. 11, 2002

Related U.S. Application Data
(60) Provisional application No. 60/301,563, filed on Jun. 28, 2001.

(51) Int. Cl. H03D 3/24

(52) U.S. Cl. 375/376

(57) ABSTRACT

A frequency locked loop for providing an output signal having an output frequency within a predetermined range of a non-integer multiple of a reference frequency. The frequency locked loop includes a voltage element, such as a voltage controlled oscillator, which produces the output signal at the output frequency. The frequency locked loop further includes a fractional divider which is operably coupled to the voltage controlled oscillator. Further, the frequency locked loop includes a frequency detector, such as a rotational frequency detector, which is operably coupled to the fractional divider. The frequency detector receives the reference signal, such as a fixed clock signal, and the output of the fractional divider signal and outputs a frequency detector signal. In one embodiment, the rotational frequency detector responds to cycle slips of 2π radians between the reference frequency and the output signal of the fractional divider. The frequency detector produces a signal which either increases or decreases charge on a capacitor which is read by the voltage element. The frequency locked loop may further incorporate a lock detector circuit for disabling the frequency detector when the output frequency is within the predetermined range.

### CROSS REFERENCE TO RELATED APPLICATIONS

This application claims priority from U.S. Provisional Patent Application entitled Fractional-N Frequency Synthesizer having Serial No.: 60/301,563 and filed on Jun. 28, 2001.

### TECHNICAL FIELD AND BACKGROUND ART

The present invention relates to frequency locked loops and more specifically to frequency locked loops in a clock and data recovery circuit.

In telecommunication, clock extraction circuits are important components of electronic receivers. Normally when data is sent to a receiver, the received data signal needs to be synched with the local clock. Since a local clock is not available which has the correct phase and frequency as that of the received data signal, a clock and data recovery circuit is necessary. In a dock and data recovery circuit, a clock signal is extracted from the received signal and used to retime the data.

FIG. 1, shows a prior art clock and data recovery circuit 100 which contains a phase locked loop (PLL) 110 and a frequency locked loop (FLL) 120. Since PLLs generally have a narrow bandwidth for acquiring a data signal, the FLL 120 is employed as a frequency acquisition device. The FLL acquires a signal having a frequency which is dose to the expected frequency of the received data signal. The signal having the acquired frequency is passed to the PLL through a it commonly shared voltage controlled oscillator (VCO). This acquired frequency signal sets the PLL so that it is operating at a frequency near that of the data frequency and can therefore acquire the data frequency signal.

In addition to receiving the acquired frequency signal, the PLL receives the data signal 130 as input. The PLL acquires the phase of the data signal so as to track the phase as it varies over time. The recovered clock is then used to retime the data.

A typical FLL in a clock and data recovery circuit 200 is shown in FIG. 2. In FIG. 2, the circuit 200 receives as input a data signal 210 into a frequency detector 220. The frequency detector 220 has a second input 250 which is part of a feedback loop wherein the output of a voltage controlled oscillator (“VCO”) is fed back into the input of the frequency detector. The frequency detector 220 detects the difference in frequency between the data signal and the signal which is output from the VCO 240. The VCO convert the voltage on the filter/capacitor 230 into an output signal whose frequency is proportional to the voltage.

One drawback of this embodiment is that the received data signal is used as input to the FLL from which the clock signal is extracted and it may be difficult to acquire the correct frequency in the presence of jitter.

In a second prior art version of the FLL as shown in FIG. 3, a reference clock signal 305 having a frequency which is a fraction of the expected frequency of the data signal is used as an input to the frequency detector 310 rather than the data signal. The reference clock signal 305 provides a low jitter signal as input to the FLL and is therefore preferable to the data signal of the embodiment of FIG. 2. In this embodiment, an integer divider circuit 320 is included so that the reference clock can be a lower frequency than the data frequency that the FLL is attempting to synthesize.

One drawback of this FLL design is that the frequency of the reference clock signal has an associated tolerance, therefore the acquired frequency (the output frequency of the VCO) will not be exactly the desired data signal frequency. This is a problem because both the FLL 300 and the PLL 350 share the VCO 360 as shown in FIG. 3A. As a result, the FLL will attempt to drive the VCO output to the reference clock frequency +/− the tolerance while the PLL will attempt to drive the VCO output to the data frequency. Thus, since the loops are interconnected wherein both loops are driving the VCO, there will be a conflict between the two competing loops. To alleviate this problem, a deadband circuit 410 as shown in FIG. 4 has been used in prior art embodiments which shuts the FLL off when the FLL has driven the output frequency of the VCO to a frequency value which is inside of the deadband range. The deadband frequency range is chosen to be within the frequency acquisition bandwidth of the PLL.

Clock and data recovery circuits are often necessary for use with received signals having different data rates. These rates are typically close in frequency so that they are within the frequency range of the VCO but are far enough apart that they are outside the capture range of the PLL. For example, the SONET standard which covers telecommunications over fiber optic cables in some parts of the world defines one particular data rate of OC48 which is 2.48832 Gbps. There is a related but slightly higher rate defined as OC48+ Wrapper which is 2.66706 Gbps. In between these two standards is the Gigabit Ethernet standard which requires a VCO output of 2.5 GHz. With such systems, designers of clock and data recovery circuits such as those described above are required to change the reference clock frequency to accommodate the different data rates. For example, assuming that the FLL multiplies the input signal by 128, if the data rate is 2.48832 GHz the reference clock must be 19.44 MHz whereas if the data rate is 2.500 GHz then the reference clock must be 19.53 MHz. Having to change the reference clock signal for each data signal having a different rate has posed a less than ideal solution.

### SUMMARY OF THE INVENTION

In a first embodiment of the invention there is provided a frequency locked loop for providing an output signal having an output frequency within a predetermined range of a non-integer multiple of a reference frequency. The frequency locked loop includes a voltage element which receives an input signal based upon a frequency detector signal. The voltage element, such as a voltage controlled oscillator, produces the output signal having the output frequency. The frequency locked loop further includes a fractional divider which is operably coupled to the voltage element and which receives the output signal. The fractional divider outputs a fractional divider signal which has a fractional divider frequency. Further, the frequency locked loop includes a frequency detector, such as a rotational frequency detector, which is operably coupled to the fractional divider. The frequency detector receives the reference signal, such as a fixed clock signal, and the fractional divider signal and outputs a frequency detector signal wherein the frequency detector signal adjusts the fractional divider signal based upon a comparison between the reference frequency and the fractional divider frequency. In one embodiment the rotational frequency detector responds to cycle slips of 2π radians between the reference frequency and the output signal of the fractional divider. The frequency locked loop may further incorporate a lock detector circuit for disabling the frequency detector when the output frequency is within the predetermined range.

A filter, such as a capacitor may be positioned at the output of the rotational frequency detector wherein charge may be added to or subtracted from the capacitor by the rotational frequency detector. As such the rotational frequency detector includes a charge pump for charging or discharging the capacitor depending on the difference in frequencies between a reference signal and the output signal of the fractional divider. Charge is added to the capacitor if the output of the voltage controlled oscillator is below the predetermined range of the non-integer multiple of the reference frequency. Charge is subtracted from the capacitor if the output frequency of the voltage controlled oscillator is above the predetermined range of the non-integer multiple of the reference frequency.

In an embodiment, the fractional divider is settable, such that, one or more divisors may be applied as an input in the form of a control signal. Additionally, the fractional divider may receive a signal which indicates the number of cycles to use a divisor when there is more than one divisor.

### BRIEF DESCRIPTION OF THE DRAWINGS

The foregoing features of the invention will be more readily understood by reference to the following detailed description, taken with reference to the accompanying drawings, in which:

FIG. 1 is a block diagram which represents one prior art embodiment of a clock and data recovery circuit which includes a phase locked loop and a frequency locked loop.

FIG. 2 is a block diagram showing a prior art frequency locked loop in a clock and data recovery circuit;

FIG. 3 is a block diagram showing another prior art embodiment of a frequency locked loop;

FIG. 3A is a block diagram showing the frequency locked loop of FIG. 3 in a clock and data recovery circuit;

FIG. 4 is a block diagram showing a prior art frequency locked loop which includes a dead band circuit;

FIG. 5 is a block diagram showing one embodiment of the invention of a frequency locked loop for use in a clock and data recovery circuit;

FIG. 5A is a graphical representation showing the designation of quadrants for Fdiv signal;

FIG. 5B is a graphical representation showing Fdiv and Fin and the determined quadrant of the difference phasor which is labeled Sample;

FIGS. 6A-C are a series of phasor diagrams which illustrate how the rotational frequency detector operates in the presence of a fractional-N divider;

FIG. 7 and 7A are two embodiments of the lock detector circuit;

FIG. 7B is a transfer function of the circuit of FIG. 7A;

FIGS. 8A-C are graphs; FIG. 8A shows the frequency of the output of the voltage controlled oscillator over time; FIG. 8B shows the voltage on the capacitor that is located at the output of the rotational frequency detector; and FIG. 8C shows the output voltage from the fractional divider toggling between two values.

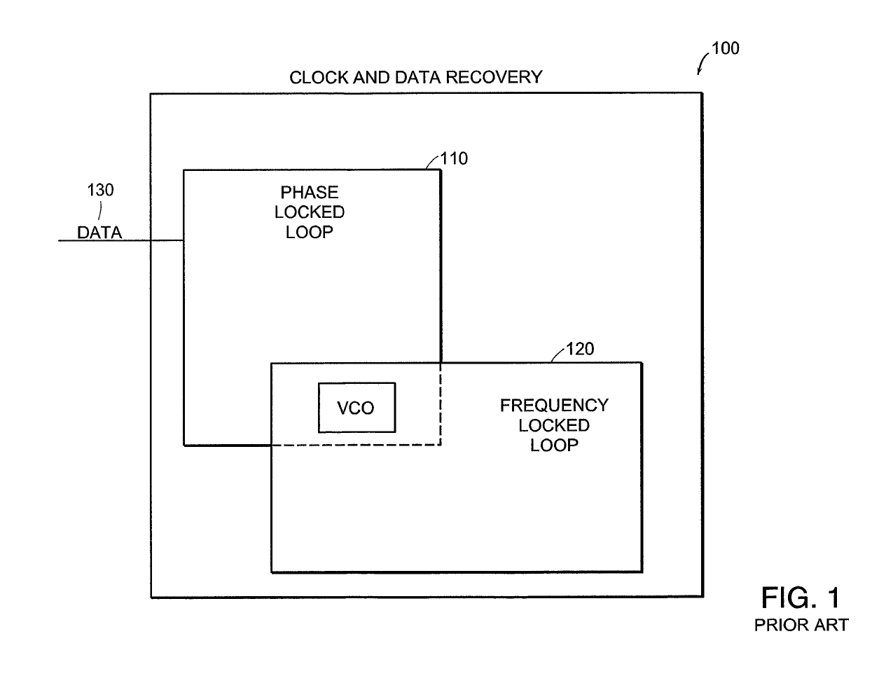

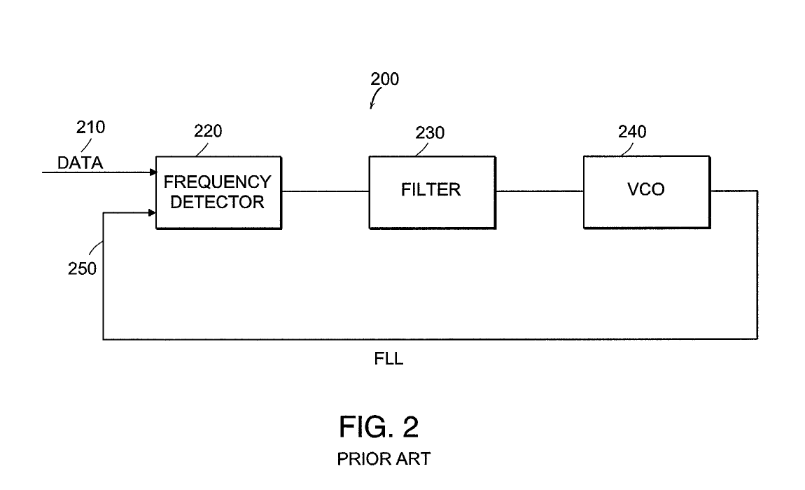

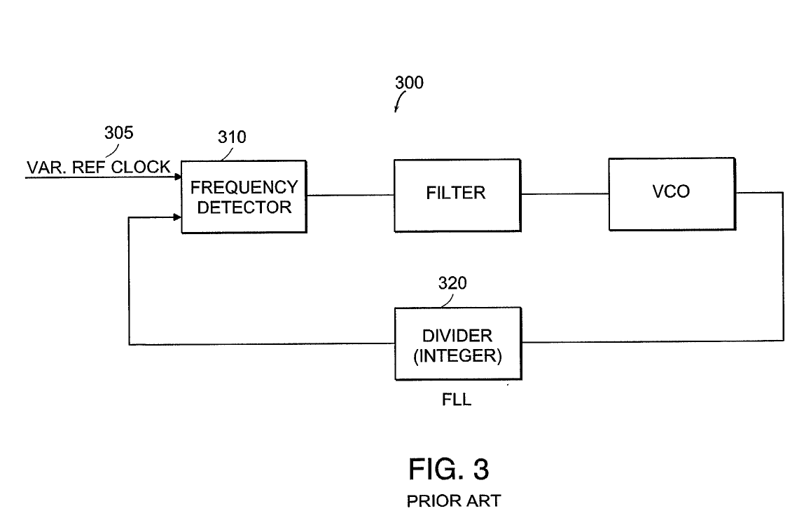

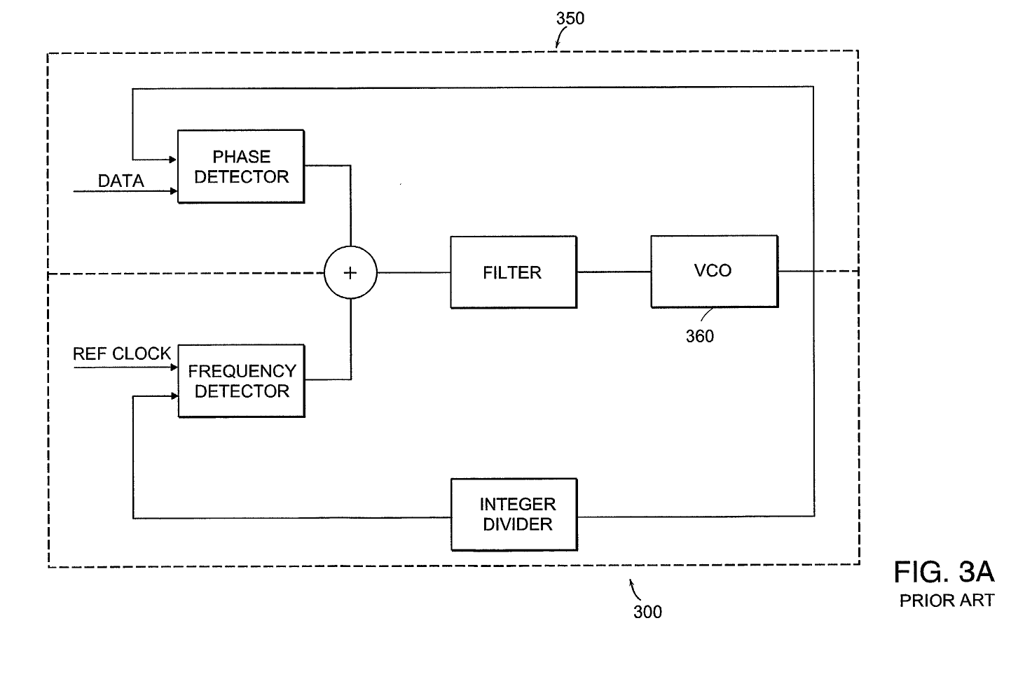

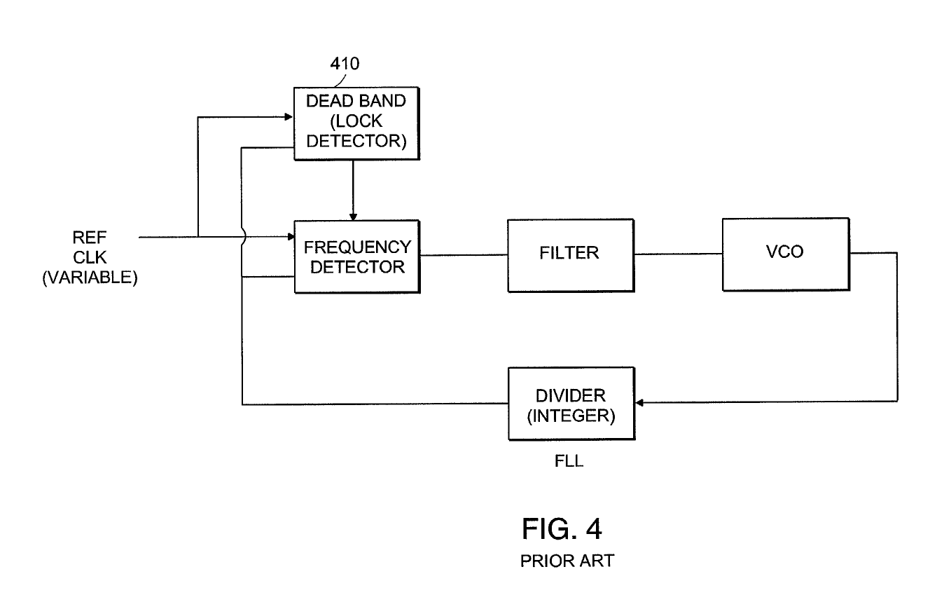

### DETAILED DESCRIPTION OF SPECIFIC EMBODIMENTS

Definitions. As used in this description and the accompanying claims, the following terms shall have the meanings indicated, unless the context otherwise requires:

A cycle slip is detected as a transition across a quadrant boundary in a phasor diagram between the difference of two phasors wherein each phasor is representative of a signal. Such a transition occurs when one of the two signals acquires a full cycle of phase (2π radians) more than the other signal.

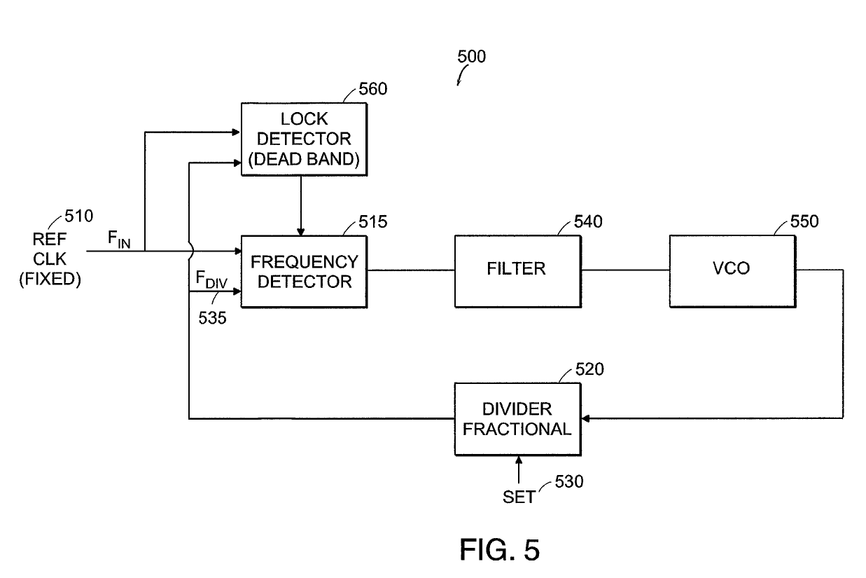

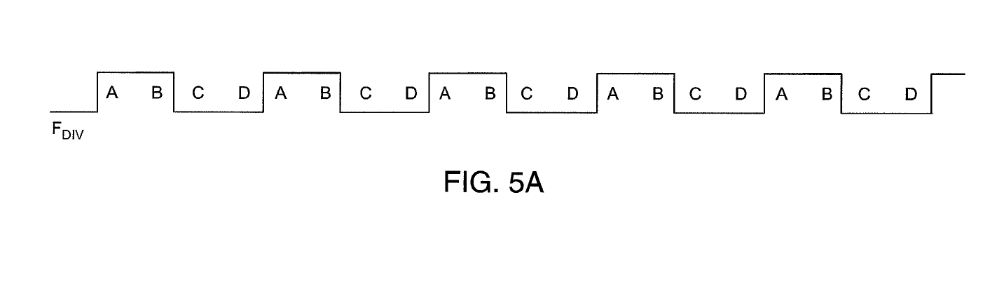

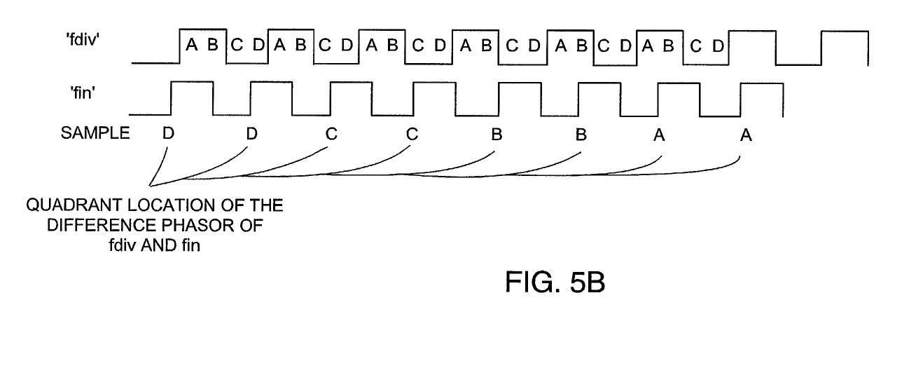

FIG. 5 is one embodiment for a frequency locked loop 500 for use in a clock and data recovery circuit. In this embodiment only a single fixed reference clock signal 510 is necessary to accommodate multiple received data rates. The frequency locked loop 500 includes a divider circuit 520, which is a fractional divider circuit. The fractional divider circuit 520 is capable of receiving an input control signal 530 which sets the divisor. Thus, multiple data rates can be accommodated with a single reference clock signal.

The circuit works in the following manner. A fixed reference clock signal (Fin) 510 is input to a frequency detector 515, for example a rotational frequency detector along with the output of divider circuit 520. Rotational frequency detectors are known to those of ordinary skill in the art and are explained in such references U.S. Pat. No. 6,055,286 to Wu and D. G. Messerschmitt, Frequency Detectors for PLL Acquisition in Timing and Carrier Recover, IEEE Transactions on Communications (September 1979) both of which are incorporated by reference herein in their entirety. The rotational frequency detector 515 (“RFD”) detects cycle slips between the two input signals measuring the difference in rotational frequency. This is accomplished with the use of logic to identify the four quadrants in a phasor diagram with respect to the output of the fractional divider circuit (Fdiv) as shown in FIG. 5A. It should be understood by one of ordinary skill in the art that a phasor diagram is a representation of a time-domain periodic signal. The reference clock signal (Fin) 510 is then used to sample the VCO clock using Fdiv 535 as shown in FIG. 5B. The samples which are the quadrant location of the difference phasor are then examined for a transition from B-C or from C-B. It should be understood by one of ordinary skill in the art that any quadrant change may be selected to determine a cycle slip, but the selected quadrant change must be used for all calculation purposes. For example, an A-B quadrant change could be used to represent a cycle slip of 2π radius. In such an embodiment a B-C or C-B change would not indicate a cycle slip and only an A-B or a B-A change would represent a cycle slip. As can be seen in FIG. 5B there is a C-B transition and therefore a cycle slip such that Fin has a greater frequency than Fdiv. When a cycle slip occurs across a quadrant boundary a signal is produced by the RFD which either adds or subtracts charge from an electrically coupled filter/capacitor 540.

The rotational frequency detector's signal to add or subtract charge is determined as follows. If the frequency of the output of the fractional divider (Fdiv) is less than the reference clock frequency (Fin) such that a cycle slip occurs, charge is added to the capacitor/filter 540 thereby increasing the electrically coupled capacitor's voltage. If the frequency of the output of the fractional divider (Fdiv) is greater than the reference clock frequency (Fin) causing a cycle slip, the capacitor/filter 540 has charge removed thereby decreasing the voltage of the capacitor. The voltage that is on the capacitor is passed to the input of a voltage controlled oscillator (VCO) 550. The VCO 550 causes the input voltage to control the oscillation frequency producing a VCO output signal. When the frequency of the output of the fractional divider is within a range of frequencies (+/−) of the reference frequency, a lock detector circuit 560 disables the operation of the frequency locked loop. The range of frequencies proximate to the reference frequency is referred to as the deadband. The deadband is selected such that all frequencies within the deadband are also within the frequency acquisition range of the phase locked loop such that the output signal of the VCO may be used by the PLL. The lock detector implements the deadband by detecting when the frequency difference is less than a predefined number, usually in parts per million (PPM). The lock detector stops the operation of the FLL by simply gating the outputs of the rotational frequency detector such that charge is not added or removed from the filter/capacitor 540. It should be understood by one of ordinary skill in the art that the frequency detector includes a charge pump, such that when the frequency detector produces a signal indicating that charge should be increased to the filter/capacitor or decreased from the capacitor that signal is passed to the charge pump which then acts as either a current source (to add charge to the capacitor) or a current sink (to remove charge from the capacitor).

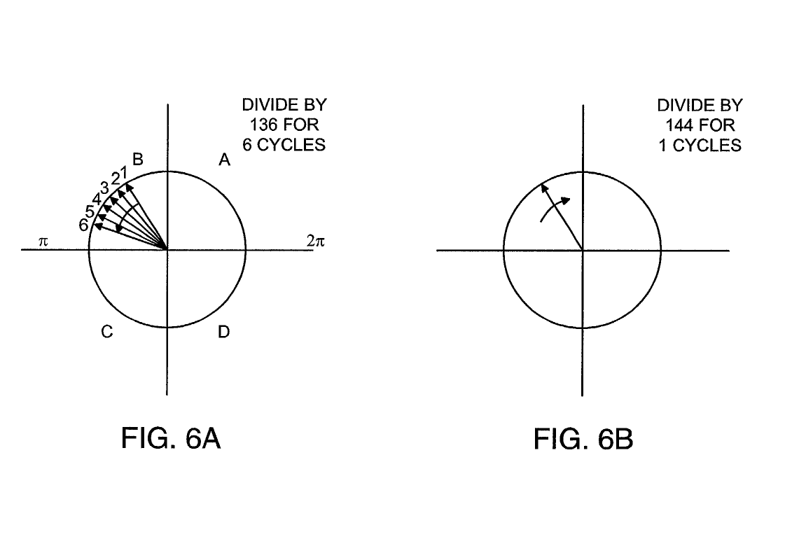

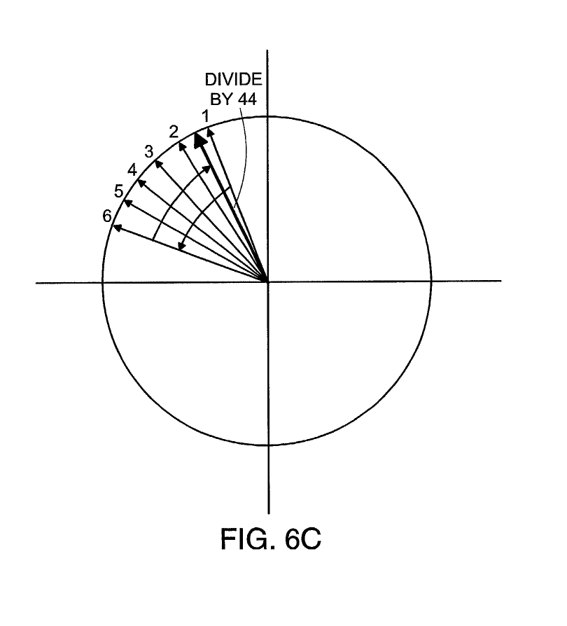

FIGS. 6A-C are a series of phasor diagrams which illustrate how the rotational frequency detector operates in the presence of the fractional divider. In the phasor diagrams that follow, each phasor represents the difference between phasors for the output of the fractional divider and the reference clock signal. The rotational arrows indicate the direction of frequency rotation.

It should be understood by one of ordinary skill that a fractional divider does not divide by a fractional amount. In actuality, a fractional divider divides by two integer values which are close to the value of the desired divisor so that the average output of the fractional divisor is equal to the desired divisor. For example, if the desired divisor is 137.1428, the fractional divider may divide by 136 for 6 cycles and then by 144 for 1 cycle such that the average is 137.1428.

The fractional divisor may be configured to receive a single divisor and then infer the second divisor by selecting the next possible integer value. For example, a fractional divider may be pre-configured to divide by integer values which are divisible by eight such that to divide by 137.4 the fractional divider will first divide by 136 and then divide by 144 which is the next highest integer. The fractional divider is preprogrammed to divide by the first divisor for a preset number of cycles and then switches to the second divisor for a preset number of cycles.

When the fractional divider divides as in the above example by 136, the rotational frequency detector senses that the output frequency of the fractional divider is slightly higher than the reference clock frequency and therefore the divisor is less than the desired 137.1428. Thus, the phasor rotates in a counter clockwise direction for each of the six cycles that the fractional divider divides by 136 as shown in FIG. 6A. When the fractional divider divides by 144 the phasor rotates in a clockwise direction as shown in FIG. 6B. When dividing by 144, the output signal of the fractional divider is lower than the frequency value of the clock signal. This causes the phasor to rotate in a clockwise direction. Such division by each of the two integer values cause the phasor to rotate in both a clockwise and counter clockwise direction and thus looks like jitter on the phasor diagram as shown in FIG. 6C.

A jitter lockout circuit which is part of the RFD rejects this jitter. As the difference phasor rotates around the unit circle and there is a pass through quadrants B to C or vice versa, this transition is detected as a cycle slip and the RFD causes charge to be added or removed from the capacitor. This first transition is allowed to occur, however all subsequent transitions are blocked by the jitter lockout circuit unless either a D or A quadrant is sensed. For example, the difference phasor for each cycle might be in the following quadrants: AAAAABABABBBBBCBCBCBCCCCCCCCCDDDDDD. The lock circuit would sense the first BC transition, but would reject the subsequent transitions. The lock circuit would not reject a subsequent transition that occurred after the difference phasor moved into a D quadrant. This jitter lock circuit prevents jitter on either the reference clock signal or jitter on the output of the fractional divider from affecting the output of the VCO.

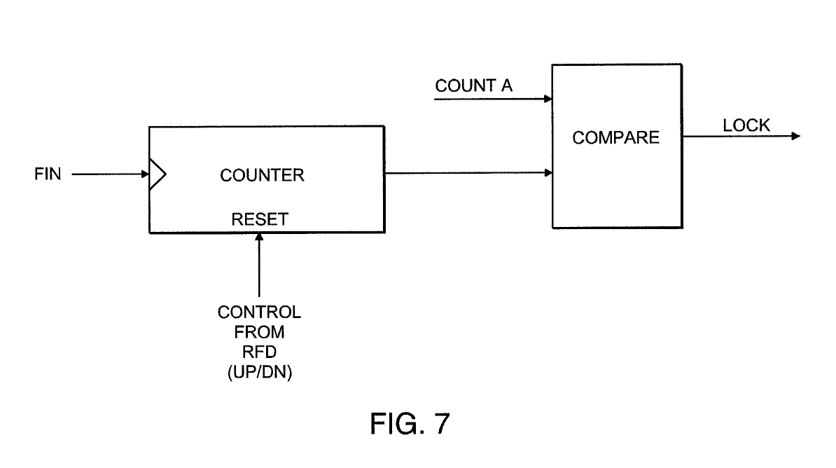

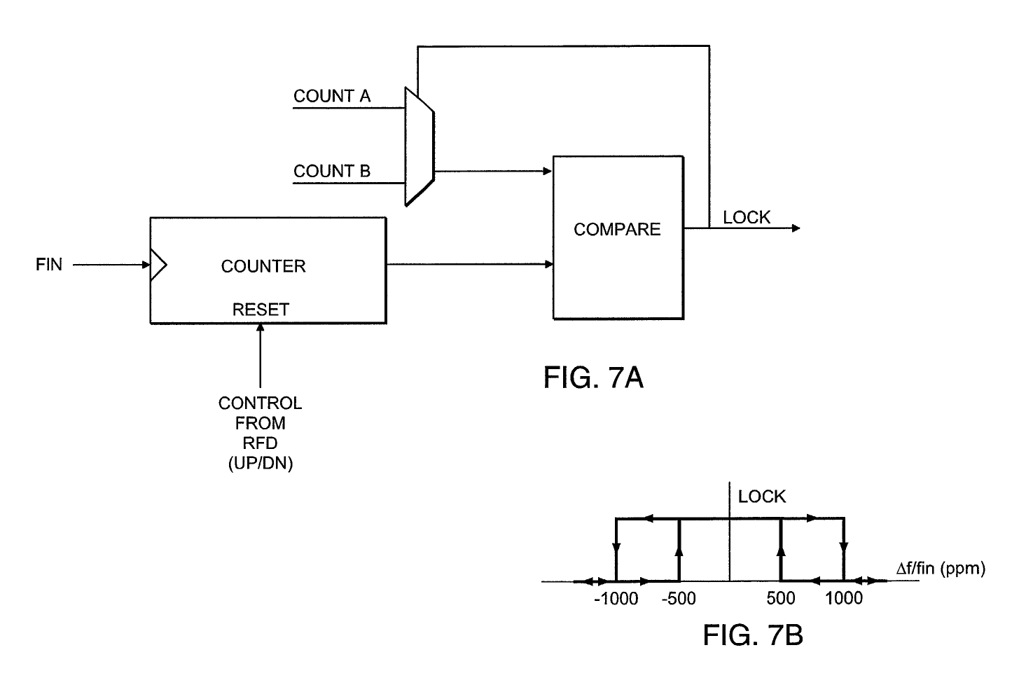

The lock detector circuit which implements the deadband is shown in FIG. 7. The lock detector detects the rate of rotation of the phasor which indicates the difference in frequency between the reference clock frequency and the output of the fractional divider circuit. By detecting the time elapsed between cycle slips, which occur when the phasor exceeds 360 degrees in rotation (2π radians), the difference in frequency between the reference clock frequency and the frequency from the output of the fractional divider can be measured.

The time between cycle slips is given by:

2πf_{refclk}t−2πf_{div}t=2π

$${t}_{1} = \frac{1}{{f}_{refclk} - {f}_{div}}$$

given that the difference in frequencies must be within the deadband and assuming that the deadband is Kppm.

$${f}_{div} = {f}_{refclk} ( 1 - \frac{k}{{10}^{6}} )$$

$$so \frac{{t}_{1}}{{T}_{refclk}} = \frac{{10}^{6}}{k}$$

where T_{refclk} is the reference clock period.

This circuit can be implemented in one embodiment with a counter which may be a synchronous or ripple counter, for example, which can be clocked by either the reference clock frequency or the frequency of the output of the fractional divider. In the embodiment as shown in FIG. 9, the control signal from the rotational frequency detector which controls whether the filter/capacitor is supplied with an increase or decrease in charge provides a reset signal for the counter. The circuit functions in the following manner. If, for example, 500 ppm is selected as the deadband then the number of “Fin” cycles to elapse between cycle slips is 1e6/500=2000. If the number of “Fin” cycle slips that elapse between outputs from the RFD is less than 2000 then the frequency difference is more than 500 ppm. In order to implement the deadband of 500 ppm, the counter counts the number of “Fin” cycles between cycle slips and this is compared to 2000 (count A). If 2000 is reached in the time between a cycle slip, the lock signal goes high and the RFD is locked out of the circuit and effectively shut off. If the counter does not reach 2000 between cycle slips the lock signal is set low and the RFD functions normally adding or subtracting charge to the filter/capacitor as described above.

In order to prevent chattering in such a lock detector circuit, a two input multiplexer is added to the circuit as shown in FIG. 7A. Count A as with the previous embodiment is set to 2000 in order to have a deadband of 500 ppm. Count B is set to 1000 so that the transfer function of the lock detector is given by the transfer function of FIG. 7B. When the counter counts to 2000 between resets the signal lock is set high. With lock set high, count B is selected where count B=1000. Lock is then returned low only if the counter counts to less than 1000 between resets. A count of 1000 corresponds to a frequency difference of 1e6/1000=1000 ppm. So the lock signal goes from low to high when the count>2000 and therefore the frequency difference<500 ppm and the lock signal goes from high to low, when the count<1000 therefore the frequency difference>1000 ppm.

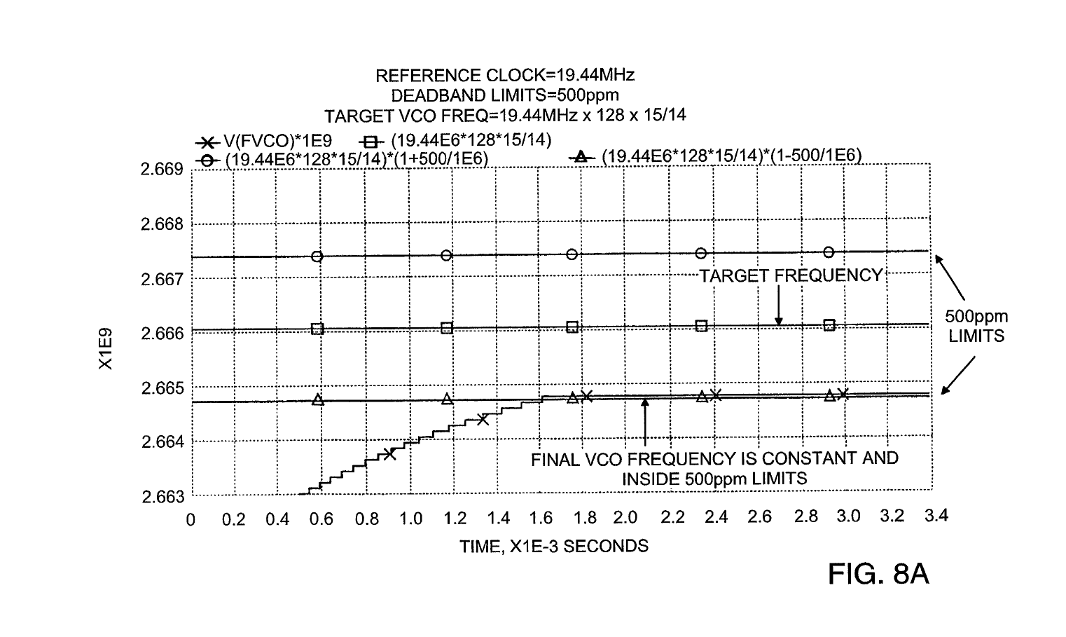

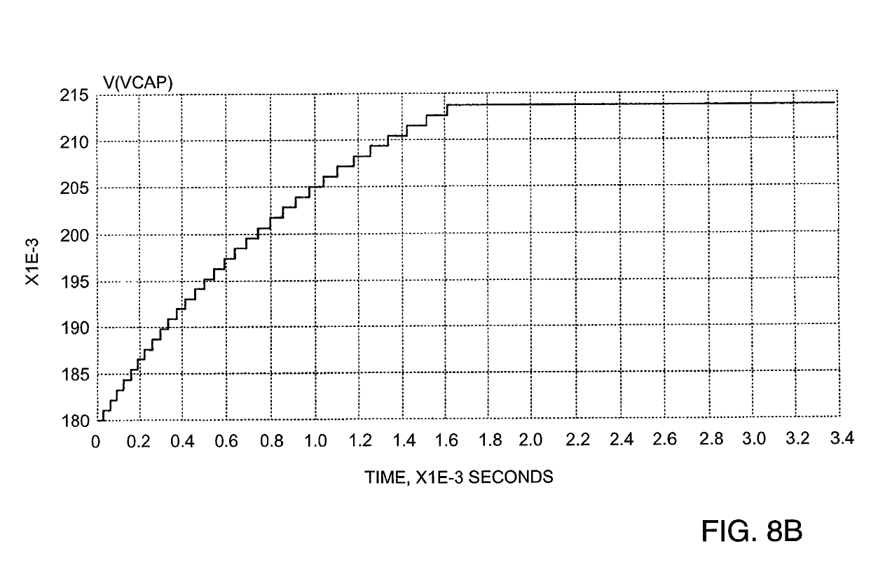

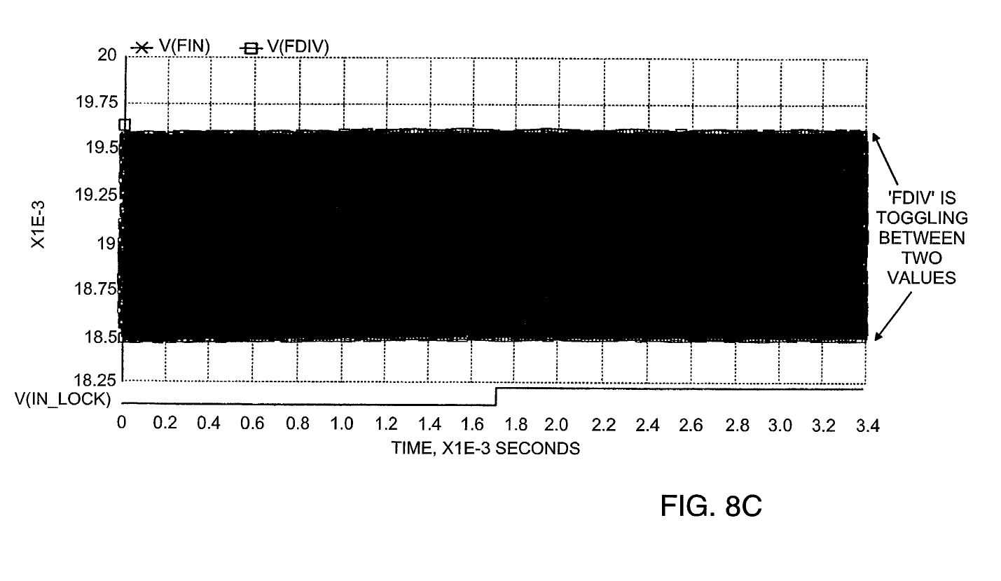

FIGS. 8A and B are sample graphs of the voltage on the capacitor that is located at the output of the rotational frequency detector and the frequency of the output of the VCO over time when attempting to obtain a frequency of 2.666 MHz within 500 ppm. FIG. 8A shows that over time, equal amounts of charge are added to the capacitor on each cycle through the frequency locked loop until the voltage reaches approximately 214 mV. It should be understood that equal amounts of charge could be removed from the capacitor if the frequency of the output of the fractional divider was greater than the frequency of the reference clock signal instead of less than as in this example. In this example, 214 mV on the capacitor is equivalent to a frequency at the output of the VCO of approximately 2.665 Ghz which is within 500 parts per million (dead band) of the expected data rate of 2.666 Ghz for this example. At 2.665 Mhz the lock detector circuit causes the FLL to turn off. Thus the frequency remains fixed from approximately 1.6×10⁻³ Seconds onward for this example. FIG. 8C is a graph which shows that the output frequency of the fractional divider (Fdiv) toggles between two frequencies values over time. The toggling occurs at the output of the fractional divider because the fractional divider is configured to divide by a first divisor for a set number of cycles and then to divide by a second divisor for a set number of cycles such that the frequency averages to the fractional divisor.

Although various exemplary embodiments of the invention have been disclosed, it should be apparent to those skilled in the art that various changes and modifications can be made which will achieve some of the advantages of the invention without departing from the true scope of the invention. These and other obvious modifications are intended to be covered by the appended claims.

What is claimed is:

1. A frequency locked loop for providing an output signal having an output frequency within a predetermined range of a non-integer multiple of a reference frequency, the frequency locked loop comprising:
a voltage element receiving an input signal based upon a frequency detector signal, the voltage element producing the output signal having the output frequency;
a fractional divider operably coupled to the voltage element receiving the output signal producing a fractional divider signal having a fractional divider frequency;
a frequency detector operably coupled to the fractional divider, the frequency detector receiving the reference signal and the fractional divider signal and outputting a frequency detector signal wherein the frequency detector signal adjusts the fractional divider signal based upon a comparison between the reference frequency and the fractional divider frequency.

2. The frequency locked loop according to claim 1, wherein the voltage element is a voltage controlled oscillator.

3. The frequency locked loop according to claim 1, wherein the frequency detector is a rotational frequency detector.

4. The frequency locked loop according to claim 1, wherein the fractional divider is settable.

5. The frequency locked loop according to claim 4, wherein the fractional divider receives a control signal to set the one or more divisors.

6. The frequency locked loop according to claim 1 further comprising a lock detector circuit for disabling the frequency detector when the output frequency is within the predetermined range.

7. The frequency locked loop according to claim 1 further comprising a filter receiving the frequency detector signal.

8. The frequency locked loop according to claim 7, wherein the filter is a capacitor.

9. The frequency locked loop according to claim 8, wherein the frequency detector signal causes additional charge to be added to the capacitor if the output frequency is below the predetermined range of the non-integer multiple of the reference frequency.

10. The frequency locked loop according to claim 8, wherein the rotational frequency detector signal removes charge from the capacitor if the output frequency is above the predetermined range of the non-integer multiple of the reference frequency.

11. The frequency locked loop according to claim 1, wherein the reference frequency is a clock signal frequency.

12. The frequency locked loop according to claim 11, wherein the clock signal frequency is not settable.

13. The frequency locked loop according to claim 11, wherein the clock signal frequency is fixed.

14. The frequency locked loop according to claim 1, wherein the fractional divider has an input for receiving a signal for determining the divisor.

15. The frequency locked loop according to claim 1, wherein the frequency detector compares the reference frequency with the fractional divider frequency to detect cycle slips.

16. The frequency locked loop according to claim 14, wherein the fractional divider receives a signal with a first and a second divisor.

17. A clock and data recovery device, the device comprising:
a phase locked loop;
a frequency locked loop having a fractional divider;
wherein the frequency locked loop provides acquisition of an acquired frequency within a range of frequencies and the phase locked loop tracks the phase of an input data signal using the acquired frequency.

18. The frequency locked loop according to claim 14, wherein the fractional divider receives a signal with a first divisor and the fractional divider infers a second divisor.

19. The frequency locked loop according to claim 16, wherein the fractional divider switches between the first and second divisor based upon a predetermined ratio.
